(19) United States
(12) Patent Application Publication
(10) Pub. No.: US 2003/0074613 A1
(43) Pub. Date: Apr. 17, 2003

(54) Apparatus for testing semiconductor device

(75) Inventor: Yasumasa Nishimura, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/121,725

(22) Filed: Apr. 15, 2002

(30) Foreign Application Priority Data
Oct. 16, 2001 (JP) 2001-317639

(51) Int. Cl. G11C 29/00

(52) U.S. Cl. 714/723

(57) ABSTRACT

When a test pattern is inputted from ALPG to semiconductor memory devices to be tested, a pattern is inputted from the semiconductor memory devices to a No-Go flag. The No-Go flag determines the quality of the semiconductor memory devices based on the pattern inputted from the semiconductor memory devices. The column-address data of a fail memory cell in the semiconductor memory device determined to be fail by the No-Go flag are stored in the corresponding column address concerning counters.

### BACKGROUND OF THE INVENTION

1. Field of the Invention

The present invention relates to an apparatus and a method for testing a semiconductor, and more specifically to a redundancy test of a semiconductor memory device.

2. Description of the Background Art

In recent years, redundant design is essential to improve yield of a large-capacity semiconductor memory device. Redundant design is a design in which spare memory cells are previously fabricated in a chip, so that the fail memory cell can be substituted by the spare memory cell, if a memory cell is found to be fail in the electrical test performed after the completion of a semiconductor memory device.

In order to save such a redundantly designed semiconductor memory device (i.e., the replacement of the above-described memory cell), it is essential to take in (store) the address data of the fail memory cell when the electrical test of the semiconductor memory device (e.g., function test) is conducted.

Therefore, a conventional semiconductor-testing apparatus for conducting the function test of a semiconductor memory device (e.g., memory tester) has a large-capacity fail memory for storing all the address data in the memory cell array.

However, since the address data of memory cells augment with augmentation in the capacity of a memory device to be tested, the capacity of the above-described fail memory must also be augmented. Therefore, there have been the problems that the price of a fail memory becomes expensive, and the price of a semiconductor-testing apparatus such as a memory tester also becomes very expensive.

Also, when the function test of a semiconductor memory device of a large capacity is conducted, the simultaneous test for a large number of memory devices (e.g., 128 devices/test station) is conducted in order to reduce the cost and time of the test. Thus, when a large number of large-capacity semiconductor memory devices are simultaneously tested, there have been problems that the capacity and dimension of the above-described fail memory must be augmented, and the price of the memory tester is further elevated. Also, such a memory tester has not been used practically because of the elevation of the price.

### SUMMARY OF THE INVENTION

The present invention has been conceived to solve the previously-mentioned problems and a general object of the present invention is to provide a novel and useful semiconductor-testing apparatus.

A more specific object of the present invention is to provide an inexpensive semiconductor-testing apparatus that can store the address data of fail memory cells.

The above object of the present invention is attained by a following semiconductor-testing apparatus.

According to an aspect of the present invention, the semiconductor-testing apparatus for testing a semiconductor memory device comprises a pattern generator for inputting test patterns to the semiconductor memory device. A determination device determines the quality of the semiconductor memory device using patterns outputted from the semiconductor memory device. An address counter stores an address data of fail memory cells fabricated in the semiconductor memory device when the determination device determines the semiconductor memory device to be fail.

Accordingly, there are provided an inexpensive semiconductor-testing apparatus that can store the address data of fail memory cells.

Other objects and further features of the present invention will be apparent from the following detailed description when read in conjunction with the accompanying drawings.

### BRIEF DESCRIPTION OF THE DRAWINGS

FIG. 1 is a block diagram for illustrating a semiconductor-testing apparatus and a semiconductor-testing method according to First Embodiment of the present invention;

FIG. 2 is a block diagram for illustrating a semiconductor-testing apparatus and a semiconductor-testing method according to Second Embodiment of the present invention; and

FIG. 3 is a block diagram for illustrating a semiconductor-testing apparatus and a semiconductor-testing method according to Third Embodiment of the present invention.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

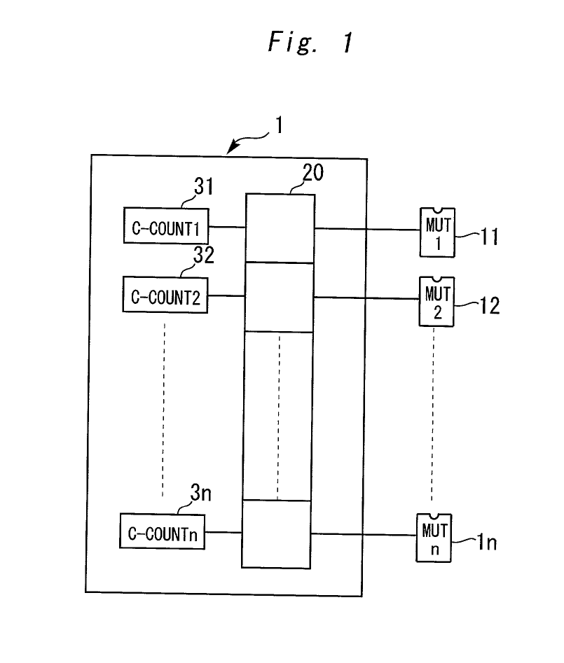

FIG. 1 is a block diagram for illustrating a semiconductor-testing apparatus and a semiconductor-testing method according to First Embodiment of the present invention. Specifically, FIG. 1 is a diagram showing a memory tester 1 having counters for storing the column-address data of a memory cell, for simultaneously testing a large number of semiconductor memory devices.

In FIG. 1, reference numeral 1 denotes a memory tester for simultaneously testing a large number of semiconductor memory devices; 11, 12, . . . , 1n denote memory devices to be tested (MUT: memory under test); 20 denotes a No-Go flag (No good-Good flag); and 31, 32, . . . , 3n denote column address concerning counters (C-COUNT) for storing the column-address data of the memory cell.

Although not shown in FIG. 1, the memory tester 1 comprises an algorithmic pattern generator (hereafter referred to as ALPG) for controlling test patterns inputted to MUTs 11, 12, . . . , 1n.

Here, the input terminal of each of MUTs 11, 12, . . . , 1n is connected to the ALPG (not shown), and the output terminal thereof is connected to the No-Go flag 20. Also, MUTs 11, 12, . . . , 1n output a pattern to the No-Go flag 20 when a test pattern is inputted from the ALPG.

The input terminal of each of No-Go flags 20 is connected to the MUTs 11, 12, . . . , 1n, and the output terminal thereof is connected to the column address concerning counters 31, 32, . . . , 3n. Also, the No-Go flags 20 determine MUTs 11, 12, . . . , 1n to be good or no good on the basis of patterns inputted from MUTs 11, 12, . . . , 1n, and display a flag corresponding to an MUT determined to be fail.

Each of the column address concerning counters 31, 32, . . . , 3n is connected to each of No-Go flags 20. Also, column address concerning counters 31, 32, . . . , 3n store the address data (column-address data in First Embodiment) of the fail memory cell of MUTs 11, 12, . . . , 1n.

Next, a semiconductor-testing method using the above-described semiconductor-testing apparatus will be described below.

First, test patterns are sequentially inputted from the ALPG to the input terminals of MUTs 11, 12, . . . , 1n.

Next, the function test to compare the pattern outputted from the output terminal of MUTs 11, 12, . . . , 1n with the expected value pattern stored in the flag 20 is performed in the No-Go flag 20. Here, the function test is an electrical test for validating the operation to write data in each memory cell in the semiconductor memory device, and the operation to read data from each memory cell.

If a memory cell in the MUT (1i) (i is an integer between 1 and n) is determined to be fail in this function test, a flag is displayed at the corresponding portion in the No-Go flag 20 connected to the MUT 1i having the fail memory cell.

At the same time when the above-described flag is displayed, the address data among the patterns outputted from the MUT (in First Embodiment, the column-address data only) is incorporated (stored) in the column address concerning counter (C-COUNT i) (3i) in real time.

Here, as the method for incorporating (storing) the above-described column-address data, for example, simply augmented (counted up) or diminished (counted down) address data among the test patterns outputted from the ALPG can be incorporated, as described later in detail (refer to Third Embodiment).

In First Embodiment, as described above, if there is a fail memory cell in an MUT (1i), the column-address data of the fail memory cell is stored in a column address concerning counter (3i) corresponding to the MUT (1i).

According to First Embodiment, the function equivalent to the function of a conventional large-capacity fail memory for storing all the address space of a semiconductor memory device can be obtained by a simple constitution of a column address concerning counter (3n). Therefore, since no expensive fail memory is required as in conventional methods, the price of a semiconductor-testing apparatus can be as greatly reduced as hundredth to one thousandth. Furthermore, the manufacturing costs of semiconductor devices can also be reduced (also in Second and Third Embodiments described later).

In First Embodiment, although the column-address data of fail memory cells are stored in column address concerning counters 31, 32, . . . , 3n, the row-address data of fail memory cells may be stored in the corresponding counters.

Second Embodiment

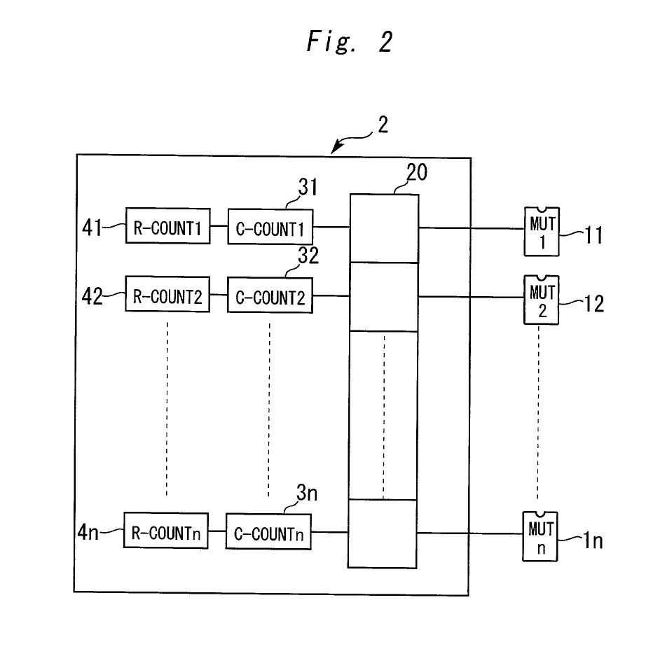

FIG. 2 is a block diagram for illustrating a semiconductor-testing apparatus and a semiconductor-testing method according to Second Embodiment of the present invention. Specifically, FIG. 2 is a diagram showing a memory tester 2 having counters for storing the column-address data of a memory cell, and counters for storing the row-address data of a memory cell, for simultaneously testing a large number of semiconductor memory devices.

In the memory tester 2 according to Second Embodiment, row address concerning counters for storing the row-address data of the memory cell are added to the memory tester 1 according to First Embodiment.

In FIG. 2, reference numeral 2 denotes a memory tester for simultaneously testing a large number of semiconductor memory devices; 11, 12, . . . , 1n in denote memory devices to be tested (MUT: memory under test); and 20 denotes a No-Go flag (No good-Good flag). Reference numerals 31, 32, . . . , 3n denote column address concerning counters (C-COUNT) for storing the column-address data of the memory cell, and numerals 41, 42, . . . , 4n denote row address concerning counter (R-COUNT) for storing the row-address data of the memory cell.

Although not shown in FIG. 2, the memory tester 2 comprises an algorithmic pattern generator (ALPG) for controlling test patterns inputted to MUTs 11, 12, . . . , 1n.

Here, the input terminal of each of MUTs 11, 12, . . . , 1n is connected to the ALPG, and the output terminal thereof is connected to the No-Go flag 20. MUTs 11, 12, . . . , 1n output a pattern to the No-Go flag 20 when a test pattern is inputted from the ALPG.

The input terminal of each of No-Go flags 20 is connected to the MUTs 11, 12, . . . , 1n, and the output terminal thereof is connected to the column address concerning counters 31, 32, . . . , 3n. Also, the output terminal of the No-Go flags 20 is connected to the row address concerning counters 41, 42, . . . , 4n through the column address concerning counters 31, 32, . . . , 3n, respectively.

The column address concerning counters 31, 32, . . . , 3n store the column-address data, which are the address data of the memory cell array; and the row address concerning counters 41, 42, . . . , 4n store the row-address data, which are the address data of the memory cell array.

Next, a semiconductor-testing method using the above-described semiconductor-testing apparatus will be described below.

First, test patterns are sequentially inputted from the ALPG to the input terminals of MUTs 11, 12, . . . , 1n. Next, the function test to check the pattern outputted from the output terminal of MUTs 11, 12, . . . , 1n is performed in the No-Go flag 20. Here, the function test is a test for validating the operation to write data in each memory cell in the semiconductor memory device, and the operation to read data from each memory cell.

If a memory cell is determined to be fail, a flag is displayed at the corresponding portion in the No-Go flag 20 connected to (corresponding to) the MUT (1i) having the fail memory cell.

At this time, the column-address data of the test pattern are incorporated in the column address concerning counters (C-COUNT 1, 2, . . . , n) (31, 32, . . . , 3n) in real time (at the same time of the function test). Furthermore, the row-address data of the test pattern are incorporated in the row address concerning counters (R-COUNT 1, 2, . . . , n) (41, 42, . . . , 4n) in real time (at the same time of the function test).

Here, as the method for incorporating (storing) the above-described address data, for example, simply augmented (counted up) or diminished (counted down) address data among the test patterns outputted from the ALPG can be incorporated, as described later in detail (refer to Third Embodiment).

In Second Embodiment, as described above, if there is a fail memory cell in an MUT (1i), the column-address data of the fail memory cell is stored in a column address concerning counter (3i) corresponding to the MUT (1i), and the row-address data of the fail memory cell is stored in a row address concerning counter (4i) corresponding to the MUT (1i).

According to Second Embodiment, as in the case of First Embodiment the function equivalent to the function of a conventional large-capacity fail memory for storing all the address space of a semiconductor memory device can be obtained by a simple constitution of a column address concerning counter and a row address concerning counter.

Therefore, since no expensive fail memory is required as in conventional methods, the price of a semiconductor-testing apparatus can be as greatly reduced as several hundredth to one thousandth.

Third Embodiment

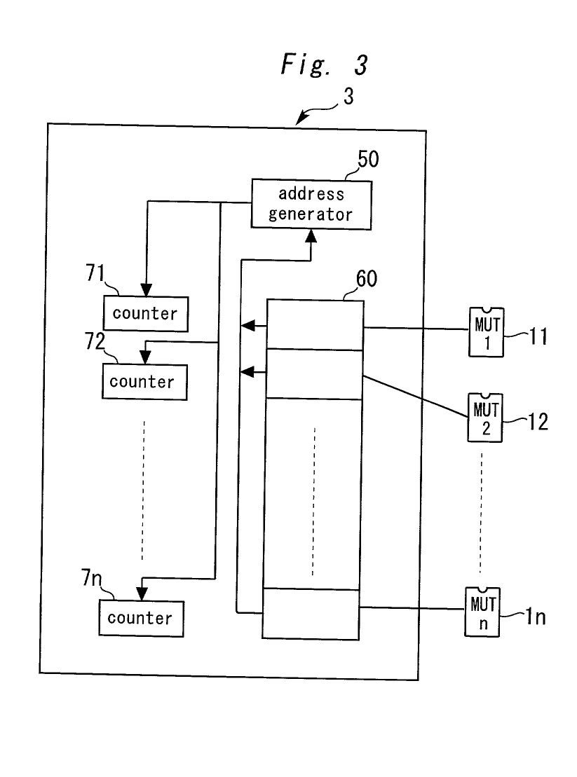

FIG. 3 is a block diagram for illustrating a semiconductor-testing apparatus and a semiconductor-testing method according to Third Embodiment of the present invention. Specifically, FIG. 3 is a block diagram for illustrating the operation to store the fail address data in a counter in real time on the basis of the result of the function test.

In FIG. 3, reference numeral 3 denotes a memory tester for simultaneously testing a large number of semiconductor memory devices; 11, 12, . . . , 1n denote memory devices to be tested (MUT: memories under test); 50 denotes an address generator; 60 denotes a pass/fail determination device; and 71, 72, . . . , 7n denote counters for storing the address data of the memory cell.

Although not shown in FIG. 3, the memory tester 3 comprises an algorithmic pattern generator (ALPG) for controlling test patterns inputted to MUTs 11, 12, . . . , 1n.

Here, the input terminal of each of MUTs 11, 12, . . . , 1n is connected to the ALPG, and the output terminal thereof is connected to the pass/fail determination device 60. MUTs 11, 12, . . . , 1n output a pattern to the pass/fail determination device 60 when a test pattern is inputted from the ALPG.

The address generator 50 is adopted to control the address data of MUTs 11, 12, . . . , 1n individually. The address generator 50 is also adopted to store the address data (for example, column-address data or row-address data) of a fail memory cell in a counter (7i) corresponding to the MUT i (1i) having the fail memory cell on the basis of the result of determination by the pass/fail determination device 60.

The pass/fail determination device 60 compares the pattern outputted from MUTs 11, 12, . . . 1n with the stored expected value pattern, and outputs the result of determination to the address generator 50.

Counters 71, 72, . . . , 7n correspond to MUTs 11, 12, . . . , 1n, respectively, and the counter (7i) corresponding to the MUT i (1i) having the fail memory cell stores the address data (for example, column-address data or row-address data) of a fail memory cell.

Next, a semiconductor-testing method using the above-described semiconductor-testing apparatus will be described below.

First, test patterns are sequentially inputted from the ALPG (not shown) to the input terminals (not shown) of MUTs 11, 12, . . . , 1n.

The pass/fail determination device 60 compares the pattern outputted from the output terminals (not shown) of MUTs 11, 12, . . . , 1n with the expected value pattern stored internally, and outputs the result of determination to the address generator 50.

Next, the address generator 50 writes (stores) the address data (for example, the column-address data or the row-address data) in the counter (7i) corresponding to the MUT i having the fail memory cell on the basis of the result of determination input from the pass/fail determination device 60. Here, the address generator 50 augments (counts up) or diminishes (counts down) address data among the test patterns outputted from the ALPG, and stores the augmented or diminished data in the counter (7i) as above-described address data.

In Third Embodiment, as described above, when the pass/fail determination device 60 determines that a memory cell in the MUT (1i) is fail, the result of the determination is transmitted to the address generator 50. Then the address generator 50 allows the counter corresponding to the MUT (1i) having a fail memory cell to store the address data of the fail memory cell.

According to Third Embodiment, the effect of incorporating fail address data in real time can be obtained in addition to the effects described in First and Second Embodiments, thereby increasing the throughput.

Although the semiconductor-testing apparatus according to Third Embodiment comprises counters 71, 72, . . . , 7n that deal with one pieces of address data (for example, the column-address data or the row-address data), the semiconductor-testing apparatus may comprise another type of counters that can deal with two pieces of address data (for example, the column-address data and the row-address data). In this case, also, the function and operation are the same as those described above.

Also, although the augmentation or diminishment of address data is performed by the address generator 50 in Third Embodiment, these may also be performed by the ALPG. In this case, since the number of component parts can be reduced, the price of the semiconductor-testing apparatus can further be reduced.

Also, the pass/fail determination device 60 in Third Embodiment may be substituted by a No-Go flag 20 in First and Second Embodiments.

This invention, when practiced illustratively in the manner described above, provides the following major effect:

There are provided an inexpensive semiconductor-testing apparatus that can store the address data of fail memory cells, a method for testing a semiconductor, and a method for manufacturing a semiconductor device.

Further, the present invention is not limited to these embodiments, but variations and modifications may be made without departing from the scope of the present invention.

The entire disclosure of Japanese Patent Application No. 2001-317639 filed on Oct. 16, 2001 containing specification, claims, drawings and summary are incorporated herein by reference in its entirety.

What is claimed is:

1. A semiconductor-testing apparatus for testing a semiconductor memory device, comprising:
a pattern generator for inputting test patterns to the semiconductor memory device;
a determination device for determining the quality of the semiconductor memory device using patterns outputted from the semiconductor memory device; and
an address counter for storing an address data of fail memory cells fabricated in the semiconductor memory device when said determination device determines the semiconductor memory device to be fail.

2. The semiconductor-testing apparatus according to claim 1, wherein said address counter has a mechanism for storing a row-address data and/or a column-address data of the fail memory cell.

3. The semiconductor-testing apparatus according to claim 1, wherein said address counter stores the address data at the same time when said determination device determines the quality of the semiconductor memory device.

4. The semiconductor-testing apparatus according to claim 2, wherein said address counter stores the address data at the same time when said determination device determines the quality of the semiconductor memory device.

5. The semiconductor-testing apparatus according to claim 1, further comprising an address generator for augmenting or diminishing the address data contained in the test patterns when said determination device determines the semiconductor memory device to be fail, and for outputting the augmented or diminished address data to said address counter.

6. The semiconductor-testing apparatus according to claim 2, further comprising an address generator for augmenting or diminishing the address data contained in the test patterns when said determination device determines the semiconductor memory device to be fail, and for outputting the augmented or diminished address data to said address counter.

7. The semiconductor-testing apparatus according to claim 3, further comprising an address generator for augmenting or diminishing the address data contained in the test patterns when said determination device determines the semiconductor memory device to be fail, and for outputting the augmented or diminished address data to said address counter.

8. The semiconductor-testing apparatus according to claim 4, further comprising an address generator for augmenting or diminishing the address data contained in the test patterns when said determination device determines the semiconductor memory device to be fail, and for outputting the augmented or diminished address data to said address counter.

9. A method for manufacturing a semiconductor device comprising a step of testing a semiconductor memory device using the semiconductor-testing apparatus according to claim 1.
